(19) United States
(12) Patent Application Publication
(10) Pub. No.: US 2024/0006848 A1
(43) Pub. Date: Jan. 4, 2024

(54) Optical Semiconductor Device

(71) Applicant: Nippon Telegraph and Telephone Corporation, Tokyo (JP)

(72) Inventors: Takuma Aihara, Tokyo (JP); Shinji Matsuo, Tokyo (JP); Tatsuro Hiraki, Tokyo (JP)

(21) Appl. No.: 18/255,153

(22) PCT Filed: Dec. 24, 2020
(86) PCT No.: PCT/JP2020/048403

§ 371 Date: May 31, 2023

(51) Int. Cl. H01S 5/10; H01S 5/125; H01S 5/12; H01S 5/00

(52) U.S. Cl. CPC H01S 5/101; H01S 5/125; H01S 5/1228; H01S 5/0078; H01S 5/1039

(57) ABSTRACT

An optical semiconductor element includes, in order, a semiconductor laser, an optical waveguide, a loop waveguide, and a ring resonator optically coupled to the loop waveguide, in which a distance between the semiconductor laser and the ring resonator is 1 μm or more and 200 μm or less.

### CROSS-REFERENCE TO RELATED APPLICATIONS

This application is a national phase entry of PCT Application No. PCT/JP2020/048403, filed on Dec. 24, 2020, which application is hereby incorporated herein by reference.

### TECHNICAL FIELD

The present invention relates to an optical semiconductor element including a semiconductor laser and an optical filter.

### BACKGROUND

Along with an increase in communication traffic in the Internet and the like, high-speed and large capacity optical fiber transmission is required. In response to this demand, development of a digital coherent communication technology using a coherent optical communication technology and a digital signal processing technology has progressed, and a 100 G system has been put into practical use. In such a communication system, a single-mode semiconductor laser is required as a local emission light source for transmission and reception.

As a typical structure of an optical resonator for single mode, a diffraction grating having a λ/4 phase shift has been used. In this structure, phase inversion is performed by a phase shifter formed in a part of a uniform diffraction grating, and single mode oscillation at a Bragg wavelength is enabled. This laser is called a λ/4 shifted distributed feedback (DFB) laser, and has already been put into practical use.

In optical communication using a phase signal, a line width of a laser related to signal quality is important, and the narrower the line width, the better.

A line width Δv of the semiconductor laser is given by Equation (1) on the basis of the relational expression of Schawlow-Townes.

Δv=hv/(4πPₒ)×v_{g}²(αₘ+αₒ)FαₘK(Lₐ/Lₚ)nₛₚ(1+α²) (1)

Here, h is a Planck constant, v is an oscillation frequency, Po is a laser output, vg is a group velocity, αₘ is a resonator loss, αₒ is a waveguide loss, F is an output coefficient, K is a Petermann's factor, Lₐ is an active layer length, Lₚ is a resonator length, nₛₚ is an emission recombination constant, and α is a line width increase coefficient. From Equation (1), it is effective to suppress the resonator loss of the semiconductor laser in order to narrow the line width of the laser.

However, when the resonator loss is suppressed and the Q value of the resonator is increased, the light is strongly localized in the phase shift region. In this localized region of strong light, a large number of carriers are consumed, and thus the carrier density decreases. A phenomenon in which a carrier distribution occurs in a resonator due to a light intensity distribution in laser as described above is called spatial hole burning. The decrease in carrier density leads to a decrease in refractive index. As a result, a distribution of the refractive index is generated inside the resonator. The distribution of the refractive index leads to a decrease in reflectance of the optical resonator and a decrease in mode selectivity, and the oscillation mode of the laser becomes unstable.

In order to suppress the influence of spatial hole burning, it is effective to reduce the coupling coefficient of the diffraction grating, but in this case, a long resonator length of about several mm is required. This means that miniaturization of the optical transceiver is hindered, and is not suitable for next-generation devices required in the future.

As one of measures for narrowing the line width, use of a light feedback effect can be mentioned. In this effect, the external mirror is formed in the semiconductor laser, and the reflected light from the mirror is returned to the semiconductor laser, so that the line width can be narrowed. In Non Patent Literature 1, a DFB laser and an etalon filter are connected via a spatial optical system, and reflected light from the etalon filter is returned to the DFB laser, thereby achieving a narrow line width. In Non Patent Literature 2, a DFB laser and a ring resonator are hybrid integrated to obtain a similar effect.

### CITATION LIST

### Non Patent Literature

Non Patent Literature 1: K. Aoyama et al., “Optical Negative Feedback for Linewidth Reduction of Semiconductor Lasers”, IEEE Photon. Technol. Lett., vol. 27, no. 4, pp. 340-343, 2015.
Non Patent Literature 2: S. Sato et al., “Performance improvement of optical negative feedback laser by reducing feedback loop length”, IEICE Electronics Express, vol. 17, No. 4, pp. 1-3, 2020.
Non Patent Literature 3: T. Aihara et al, “Membrane buried-heterostructure DFB laser with an optically coupled III-V/Si waveguide”, Opt. Express, vol. 27, No. 25, pp. 36438-36448, 2019.

### SUMMARY

### Technical Problem

However, the configuration of the optical filter has a problem of increasing the overall device size. In addition, since the distance between the laser and the optical filter is long and a phase delay occurs, the frequency noise on the high frequency side cannot be reduced, and as a result, the narrowing of the line width is limited.

In addition, a measure for increasing the Q value of the optical filter in order to increase the frequency noise attenuation amount is conceivable, but in this case, the phase delay in the optical filter becomes large, the frequency noise on the high frequency side cannot be reduced, and as a result, the narrowing of the line width is limited.

As described above, it is difficult to achieve a small semiconductor laser that reduces frequency noise in a wide frequency range.

### Solution to Problem

In order to solve the above-described problem, an optical semiconductor element according to embodiments of the present invention includes, in order, a semiconductor laser, an optical waveguide, a loop waveguide, and a ring resonator optically coupled to the loop waveguide, in which a distance between the semiconductor laser and the ring resonator is 1 μm or more and 200 μm or less.

An optical semiconductor element according to embodiments of the present invention includes, in order, a semiconductor laser, an optical waveguide, and a DBR grating, in which a distance between the semiconductor laser and the DBR grating is 1 μm or more and 200 μm or less.

### Advantageous Effects of Embodiments of the Invention

According to embodiments of the present invention, it is possible to provide a compact optical semiconductor element that reduces frequency noise in a wide frequency range.

### BRIEF DESCRIPTION OF THE DRAWINGS

FIG. 1 is a schematic view illustrating a configuration of an optical semiconductor element according to a first embodiment of the present invention.

FIG. 2A is a bird's-eye perspective view illustrating a configuration of a semiconductor laser of the optical semiconductor element according to the first embodiment of the present invention.

FIG. 2B is a front cross-sectional view illustrating a configuration of a semiconductor laser of the optical semiconductor element according to the first embodiment of the present invention.

FIG. 3 is a view illustrating characteristics of the optical semiconductor element according to the first embodiment of the present invention.

FIG. 4 is a view illustrating characteristics of the optical semiconductor element according to the first embodiment of the present invention.

FIG. 5 is a schematic diagram illustrating a configuration of an optical semiconductor element according to a second embodiment of the present invention.

FIG. 6 is a view illustrating characteristics of the optical semiconductor element according to the second embodiment of the present invention.

FIG. 7 is a schematic view illustrating a configuration of an optical semiconductor element according to embodiments of the present invention.

FIG. 8 is a schematic view illustrating a configuration of an optical semiconductor element according to embodiments of the present invention.

### DETAILED DESCRIPTION OF ILLUSTRATIVE EMBODIMENTS

### First Embodiment

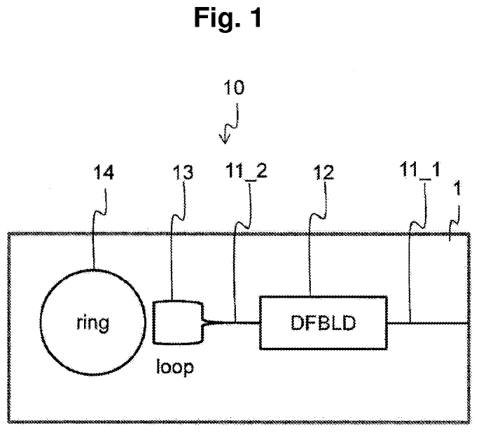

An optical semiconductor element according to a first embodiment of the present invention will be described with reference to FIGS. 1 to 4.

### Configuration of Optical Semiconductor Element

As illustrated in FIG. 1, an optical semiconductor element 10 according to the first embodiment includes a first optical waveguide 11_1, a semiconductor laser 12, a second optical waveguide 11_2, and an optical filter. The optical filter in the present embodiment includes a loop waveguide 13 and a ring resonator 14 coupled to the loop waveguide 13. Even if the first optical waveguide 11_1 is not provided, laser light can be directly output from an end surface (right end in the drawing) of the semiconductor laser 12.

The optical semiconductor element 10 has a stacked structure on a Si substrate 1. In the optical semiconductor element 10, the second optical waveguide 11_2 and the optical filter include, for example, a Si waveguide including a Si core and SiO2 cladding. Since the Si waveguide has a large difference in refractive index between the core and the cladding, the Si waveguide enables sharp bending, and is suitable for miniaturization and high integration. The width of the waveguide structure used for the second optical waveguide 11_2 and the optical filter is 400 nm, and the layer thickness of the waveguide core is 220 nm.

The length of the second optical waveguide 11_2 connecting the semiconductor laser 12 and the loop waveguide 13 is about 50 μm.

The loop waveguide 13 in the optical filter may have a configuration in which the light incident from the semiconductor laser 12 is coupled with the ring resonator 14 and returns to the semiconductor laser 12, and may have a polygonal shape in which the upper surface shape is curved as illustrated in FIG. 1. Alternatively, the upper surface shape may be a circle or an ellipse.

The loop waveguide 13 has a radius of about 20 μm if the upper surface shape is circular.

The ring resonator 14 in the optical filter may have a structure in which the light coupled and incident from the loop waveguide 13 circulates, and may have a circular upper surface shape as illustrated in FIG. 1. Alternatively, the upper surface shape may be an ellipse or a polygon. The ring resonator 14 has a radius of about 50 μm if the upper surface shape is circular.

The gap between the loop waveguide 13 and the ring resonator 14 is 50 μm, and may be any length as long as optical coupling can be performed.

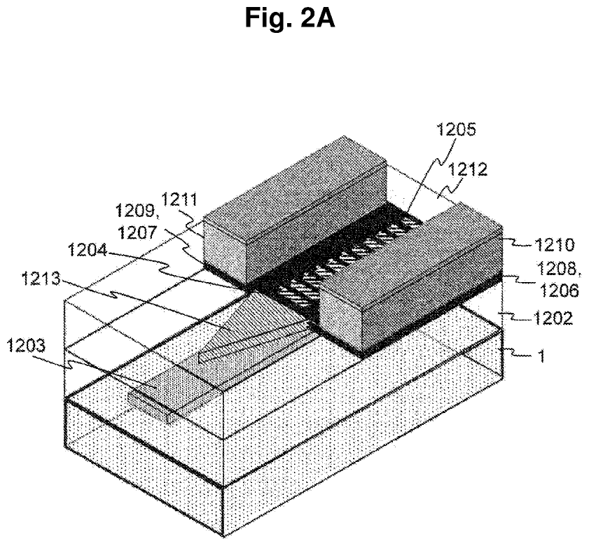

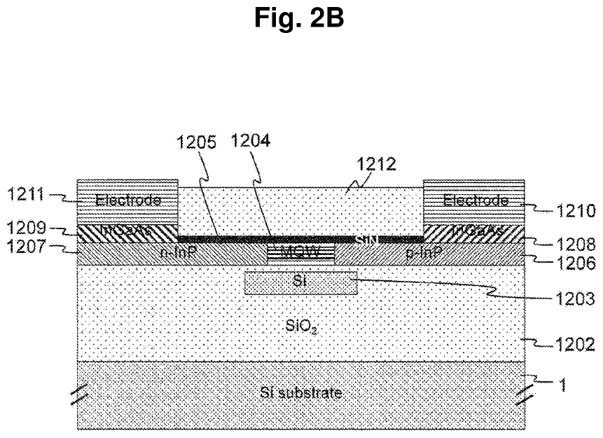

As illustrated in FIGS. 2A and 2B, the semiconductor laser 12 has a thin film lateral current injection structure. The semiconductor laser 12 includes a multiple quantum well (MQW) 1204, which is an active layer (light emitting layer), a SiN grating 1205, and SiO₂ 1212 in order on a SiO₂ cladding 1202 covering a Si waveguide (core) 1203 on the Si substrate 1. In order to laterally inject a current into the MQW 1204, a p-InP 1206 and an n-InP 1207 are provided on both sides of the MQW 1204. A p-InGaAs 1208 and a p-electrode 1210 are provided in order on the p-InP 1206. An n-InGaAs 1209 and an n-electrode 1211 are provided in order on the n-InP 1207. An InP tapered waveguide 1213 is connected to the MQW 1204 in the guiding direction of the laser light, and the laser light is coupled from the InP tapered waveguide 1213 to the Si waveguide 1203 to guide the Si waveguide 1203. Also, the device length of the semiconductor laser 12 is 500 μm.

In this structure, since optical confinement of the active layer (MQW) 1204 is large, laser oscillation can be performed even if the resonator length is short, which is advantageous for miniaturization. The InP tapered waveguide 1213 having a length of about 10 μm can also couple laser light to the Si waveguide 1203 (Non Patent Literature 3).

### Operation of Optical Semiconductor Element

The laser light emitted from the semiconductor laser 12 passes through the second optical waveguide 11_2 and enters the ring resonator 14. Frequency fluctuations of light are converted into amplitude fluctuations by the ring resonator 14.

The light having the converted amplitude fluctuation returns to the semiconductor laser 12. This amplitude fluctuation acts to cancel the frequency fluctuation.

Specifically, the increase (attenuation) of the oscillation frequency is changed to the increase (attenuation) of the amplitude by the ring resonator 14, and the amplitude of the feedback light is increased (attenuated). As the feedback light increases (attenuates), the photon density of the DFB laser increases (attenuates), and the refractive index inside the DFB laser decreases (increases). Since the decrease in the refractive index decreases (increases) the oscillation frequency, the feedback light acts as negative feedback so as to cancel the change in the oscillation frequency.

Next, the feedback length dependency of the optical semiconductor element will be described. The feedback length is a distance between the semiconductor laser 12 and the ring resonator 14. Specifically, the feedback length is a distance from the optical filter side end of the semiconductor laser 12 to a portion where the ring resonator 14 couples the loop waveguide 13.

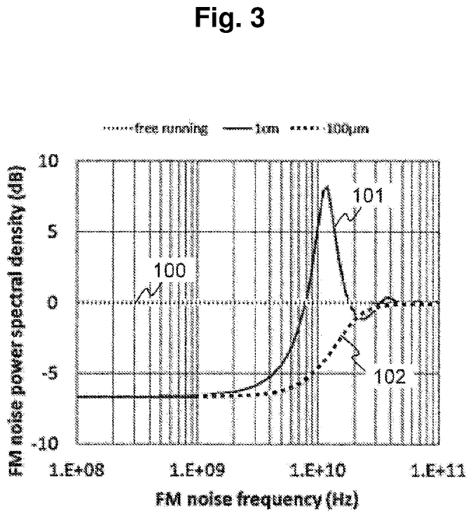

FIG. 3 illustrates a calculation result of the spectrum of the frequency noise. The spectrum of the frequency noise was calculated on the basis of the optical transfer function. Results of a case where the feedback length is 1 cm (101 in the drawing) and a case where the feedback length is 100 μm (102 in the drawing) are illustrated, and in addition, results of a case where there is no feedback length (free running, 100 in the drawing) are also illustrated for comparison.

In both cases where the feedback length is 1 cm and 100 μm, the frequency noise is attenuated on the low frequency side and is not attenuated on the high frequency side. In a case where the feedback length is 1 cm, frequency noise attenuates at about 8 GHz or less. In a case where the feedback length is 100 μm, frequency noise attenuates at about 30 GHz or less. As described above, as the feedback length increases, the frequency noise can be attenuated in a wide frequency range. This is because a phase delay occurs when the feedback length (distance between the semiconductor laser 12 and the ring resonator 14) is long.

In a case where the feedback length is long (1 cm), damping occurs at about 10 GHz. This is because the phase is inverted and positive feedback is working. As described above, in a case where the feedback length is long, the frequency noise may be increased as compared with a case where the feedback length is not provided. On the other hand, in a case where the feedback length is short (100 μm), damping does not occur.

As described above, by reducing the feedback length to, for example, about 100 μm, the band of noise attenuation can be expanded without causing damping. Here, by setting the feedback length to 200 μm or less, the band of noise attenuation can be expanded without causing damping. In consideration of the configuration of the element, the feedback length is desirably 5 μm or more, and can be 1 μm or more.

In the conventional element configuration, since the feedback light is returned to the laser through the spatial optical system, the feedback length becomes long. Therefore, damping may occur, and the band of noise attenuation cannot be expanded. Also in an element configuration by hybrid integration, since optical coupling between different chips requires a length of several mm, damping may occur similarly, and the band of noise attenuation cannot be expanded.

On the other hand, in the optical semiconductor element 10 according to the present embodiment, the semiconductor laser 12 and the optical filter can be monolithically integrated on the Si substrate. In addition, the taper length can be shortened by using a thin film lateral current injection structure for the semiconductor laser 12 structure. As described above, the semiconductor laser 12 and the optical filter can be connected with a short feedback length. As a result, the frequency noise attenuation band can be expanded.

Next, the Q-value dependency of the characteristics of the optical semiconductor element 10 according to the present embodiment will be described.

In the optical semiconductor element 10 according to the present embodiment, since the ring resonator 14 is used for the optical filter, the increase in the phase delay can be suppressed by adjusting the Q value of ring resonator 14, and the band of the frequency noise attenuation can be expanded.

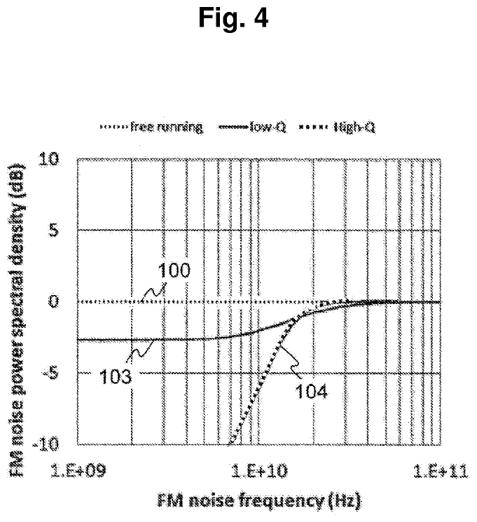

FIG. 4 illustrates calculation results of the spectrum of the frequency noise in a case where the Q value of the ring resonator 14 is low (103 in the drawing) and in a case where the Q value is high (104 in the drawing). The calculation was made considering the low Q-value as 1000 and the high Q-value as 10,000.

When the Q value is low, frequency noise attenuates at about 30 GHz or less, and a noise attenuation amount is about 2.5 dB.

When the Q value is high, frequency noise attenuates at about 20 GHz or less, and a noise attenuation amount is about 10 dB or more.

As described above, when the Q value is low, the noise attenuation amount is small and the frequency noise attenuation band is wide, and when the Q value is high, the noise attenuation amount is large and the frequency noise attenuation is narrow. As described above, the attenuation of the frequency noise varies depending on the G value, and there is a trade-off relationship between the band of the noise attenuation and the attenuation amount.

In the optical semiconductor element 10 according to the present embodiment, for example, the Q value can be reduced (for example, Q value=100 to 1000) by reducing the distance between the ring resonator 14 and the loop waveguide 13 (for example, 0.1 to 0.3 μm), so that the frequency noise attenuation band can be widened. Alternatively, since the Q value can be increased (for example, Q value=1000 to 10000) by increasing the distance between the ring resonator 14 and the loop waveguide 13 (for example, 0.3to 0.5 μm), the frequency noise attenuation amount can be increased.

Alternatively, since the Q value can be reduced (for example, Q value=100 to 1000) by reducing the diameter of the ring resonator 14 (for example, 10 to 100 μm), the frequency noise attenuation band can be widened. Alternatively, since the Q value can be increased (for example, Q value=1000 to 10000) by increasing the diameter of the ring resonator 14 (for example, 100 to 1000 μm), the frequency noise attenuation amount can be increased.

As described above, in the optical semiconductor element 10 according to the first embodiment, the frequency noise attenuation can be changed by changing the configuration to change the Q value.

### Second Embodiment

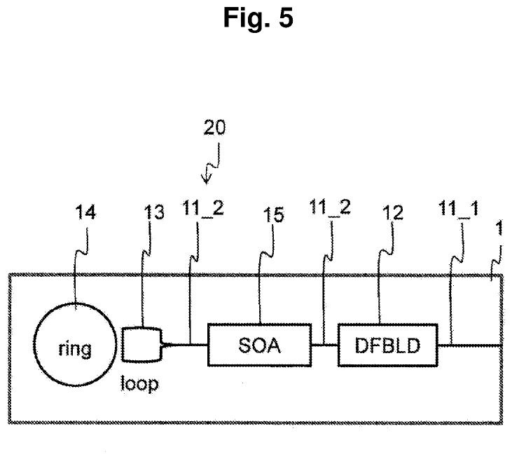

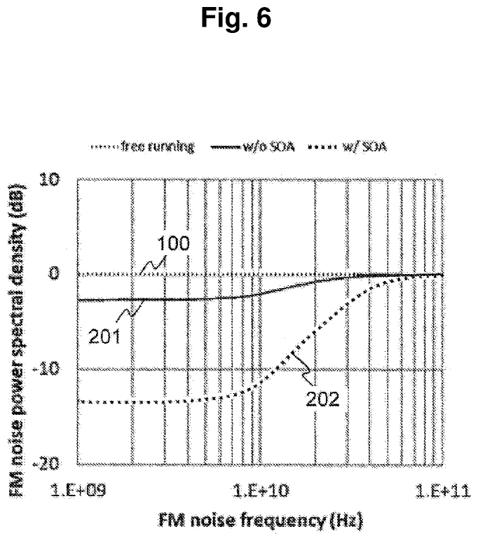

An optical semiconductor element according to a second embodiment of the present invention will be described with reference to FIGS. 5 and 6.

As illustrated in FIG. 5, the optical semiconductor element 20 according to the second embodiment includes the semiconductor optical amplifier 15 in any of the second optical waveguides 11_2 between the semiconductor laser 12 and the loop waveguide 13 in addition to the configuration of the optical semiconductor element 20 according to the first embodiment.

As described above, there is a trade-off relationship between the band of noise attenuation and the attenuation amount with respect to the change in the Q value, and when the Q value is low, the frequency noise attenuation band is wide, but the noise attenuation amount is small.

Therefore, in the optical semiconductor element 20 according to the present embodiment, the Q value is set low, and the laser light is amplified by the semiconductor optical amplifier 15 to improve the noise attenuation amount.

The Q value can be reduced by reducing the distance between the ring resonator 14 and the loop waveguide 13 in the optical semiconductor element 20. For example, by setting the distance between the ring resonator 14 and the loop waveguide 13 to about 0.1 to 0.2 μm, the Q value can be set to about 100 to 1000.

The Q value can be reduced by reducing the diameter of the ring resonator 14. For example, the Q value can be set to about 100 to 1000 by setting the diameter of the ring resonator 14 to about 10 to 100 μm.

In the present embodiment, the distance between the ring resonator 14 and the loop waveguide 13 (or the diameter of the ring resonator 14) is 0.3 μm, and the Q value is set to 1000.

Since the semiconductor optical amplifier 15 can amplify the amplitude fluctuation to be fed back, it is possible to increase the feedback gain and increase the noise attenuation amount. Since the frequency band of the semiconductor optical amplifier 15 is as high as several THz, broadband noise attenuation becomes possible. That is, the semiconductor optical amplifier 15 makes it possible to achieve both widening of the frequency noise attenuation and improvement of the noise attenuation amount.

As illustrated in FIG. 6, in both a case where the SOA is not provided (201 in FIG. 6) and a case where the SOA is provided (202 in FIG. 6), the frequency noise can be attenuated at about 50 GHz or less. In a case where the SOA is not provided, the noise attenuation amount is about 2.5 dB. In a case where the SOA is provided, the noise attenuation amount is about 13 dB.

As described above, according to the optical semiconductor element 20 of the first embodiment, the frequency noise can be attenuated in the wide area, and the noise attenuation amount can be improved.

As described above, according to the optical semiconductor element 20 of the first embodiment, the optical semiconductor element having the low frequency noise can be achieved.

In the embodiment of the present invention, an example in which the optical filter is configured by the Si waveguide has been described, but the present invention is not limited thereto. For example, an InP waveguide may be used. According to the InP waveguide, since both the semiconductor laser 12 and the waveguide are made of the InP-based semiconductor material, connection between different materials of the InP-based semiconductor laser and the Si waveguide is not required, and further downsizing and widening of the frequency noise attenuation can be achieved.

A SiN waveguide or a SiOₓN_{y} waveguide may be used. Since SiN has a lower thermo-optical coefficient than Si or InP, SiN is stable against thermal fluctuation. Therefore, intrinsic frequency noise is reduced. In addition, since optical power resistance is high, a non-linear optical effect is less likely to occur even at high power, and this is effective for high optical output.

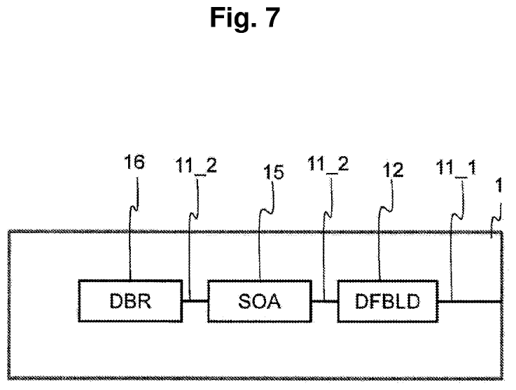

In the embodiment of the present invention, the example in which the ring resonator is used for the optical filter has been described, but for example, the DBR grating 16 may be used. Further miniaturization can be expected as compared with the ring resonator. As illustrated in FIG. 7, in the case of application to the second embodiment, the Q value can be set low by reducing the depth of the diffraction grating groove of the DBR grating 16. In this case, the Q value can be set to 50 to 100 by setting the diffraction grating to a depth of 0.01 to 0.2 μm.

Here, by setting the distance (feedback length) between the semiconductor laser and the DBR grating to 200 μm or less, the band of noise attenuation can be expanded without causing damping. In consideration of the configuration of the element, the feedback length is desirably 5 μm or more, and can be 1 μm or more.

This configuration may be applied to the optical semiconductor element 10 according to the first embodiment, and a semiconductor optical amplifier may not be disposed.

On the other hand, compared with the DBR grating, the ring resonator can be easily formed, and the Q value can be changed.

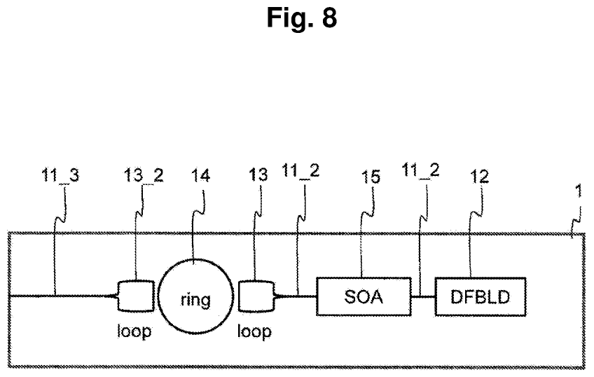

In the embodiment of the present invention, the example in which the structure for extracting the laser light is not provided in the ring resonator has been described. However, as illustrated in FIG. 8, a coupling waveguide including a second loop waveguide 13_2 and a third optical waveguide 11_3 may be further provided in the optical semiconductor element 20 according to the second embodiment, the laser light may be extracted, and the laser light may be output from the coupling waveguide. In this case, since the laser light is output only from the distal end of the coupling waveguide (only in the left direction in the drawing), an output twice the output in the case where the laser light is output from both sides can be obtained, and high output can be achieved. This configuration may be applied to the optical semiconductor element 10 according to the first embodiment.

In the embodiment of the present invention, the example of using the semiconductor laser in which the current is injected in the lateral direction has been described, but a semiconductor laser in which the current is injected in the longitudinal direction may be used.

The embodiments of the present invention show examples of the structures, dimensions, materials, and the like of the respective components in the configuration, manufacturing method, and the like regarding optical semiconductor element, but the present invention is not limited thereto. An optical semiconductor element is only required to exhibit its functions and achieve effects.

### INDUSTRIAL APPLICABILITY

Embodiments of the present invention can be applied to local light sources for transmission and reception in digital coherent communication.

### REFERENCE SIGNS LIST

10 Optical semiconductor element
11_1, 11_2 Optical waveguide
12 Semiconductor laser
13 Loop waveguide
14 Ring resonator
15 Semiconductor Optical Amplifier

1-7. (canceled)

8. An optical semiconductor element, comprising:
a semiconductor laser;
an optical waveguide;
a loop waveguide; and
a ring resonator optically coupled to the loop waveguide, wherein a distance between the semiconductor laser and the ring resonator is in a range of 1 μm to 200 μm, and wherein components of the optical semiconductor element are in the following order: the semiconductor layer, the optical waveguide, the loop waveguide, and the ring resonator.

9. The optical semiconductor element according to claim 8, further comprising a semiconductor optical amplifier provided in the optical waveguide.

10. The optical semiconductor element according to claim 9, wherein a distance between the loop waveguide and the ring resonator is in a range of 0.1 μm to 0.5 μm.

11. The optical semiconductor element according to claim 9, wherein a radius of the ring resonator is in a range of 10 μm to 1000 μm.

12. The optical semiconductor element according to claim 9, further comprising:
an additional loop waveguide coupled to a first portion of the ring resonator, the first portion of the ring resonator being different from a second portion of the ring resonator to which the loop waveguide is coupled; and
an additional optical waveguide connected to the additional loop waveguide.

13. The optical semiconductor element according to claim 8, wherein a distance between the loop waveguide and the ring resonator is in a range of 0.1 μm to 0.5 μm.

14. The optical semiconductor element according to claim 8, wherein a radius of the ring resonator is in a range of 10 μm to 1000 μm.

15. The optical semiconductor element according to claim 8, further comprising:
an additional loop waveguide coupled to a first portion of the ring resonator, the first portion of the ring resonator being different from a second portion of the ring resonator to which the loop waveguide is coupled; and
an additional optical waveguide connected to the additional loop waveguide.

16. An optical semiconductor element, comprising:
a semiconductor laser;
an optical waveguide; and
a distributed Bragg reflector (DBR) grating, wherein a distance between the semiconductor laser and the DBR grating is in a range of 1 μm to 200 μm, wherein components of the optical semiconductor element are in the following order: the semiconductor layer, the optical waveguide, the DBR grating.

17. The optical semiconductor element according to claim 16, further comprising a semiconductor optical amplifier in the optical waveguide.

18. The optical semiconductor element according to claim 17, wherein a depth of a diffracting grating groove of the DBR grating is in a range of 0.01 μm to 0.2 μm.

19. The optical semiconductor element according to claim 17, wherein the distance between the semiconductor laser and the DBR grating is greater than 5 μm.

20. The optical semiconductor element according to claim 16, wherein a depth of a diffracting grating groove of the DBR grating is in a range of 0.01 μm to 0.2 μm.

21. The optical semiconductor element according to claim 16, wherein the distance between the semiconductor laser and the DBR grating is greater than 5 μm.
